(19) United States
(12) Patent Application Publication
(10) Pub. No.: US 2021/0043657 A1
(43) Pub. Date: Feb. 11, 2021

(54) ARRAY SUBTRATE, MANUFACTURING METHOD THEREOF AND DISPLAY PANEL

(71) Applicant: HKC CORPORATION LIMITED, Shenzhen (CN)

(72) Inventor: Zhenli SONG, Chongqing (CN)

(21) Appl. No.: 17/041,433

(22) PCT Filed: Nov. 30, 2018
(86) PCT No.: PCT/CN2018/118422

§ 371 Date: Sep. 24, 2020

(30) Foreign Application Priority Data
Nov. 12, 2018 (CN) 201811337227.X

(51) Int. Cl. H01L 27/12

(52) U.S. Cl. CPC H01L 27/124; H01L 27/1248; H01L 27/1259

(57) ABSTRACT

The application discloses an array substrate, a manufacturing method of the array substrate and a display panel. The array substrate includes: a substrate, Metal 1, an insulating layer, a semiconductor layer, a barrier layer, Metal 2, a first passivation layer, a pixel electrode, a first contact hole and a second contact hole, where the Metal 2 includes a source electrode and a drain electrode; the pixel electrode is disposed above the first passivation layer; the first contact hole connects the pixel electrode and the drain electrode; the second contact hole connects the drain electrode and the semiconductor layer; the first contact hole and the second contact hole overlap in a direction perpendicular to the array substrate.

This application claims the priority to the Chinese Patent Application No. CN201811337227X, filed with National Intellectual Property Administration, PRC on Monday, Nov. 12, 2018 and entitled “ARRAY SUBSTRATE, MANUFACTURING METHOD THEREOF AND DISPLAY PANEL”, which is incorporated herein by reference in its entirety.

### TECHNICAL FIELD

The present application relates to the field of display technology, in particular to an array substrate, a manufacturing method thereof and a display panel.

### BACKGROUND

It should be understood that the statements herein merely provide background information related to the present application and do not necessarily constitute the conventional art.

Taking a liquid crystal display panel as an example, the liquid crystal display panel mainly uses electric field to control the rotation of liquid crystal molecules, so that light can pass through the liquid crystal molecules to display images. Etch Stop Layer (ESL) structure is generally used to prevent back channel etching damage in the structure of array substrate, but a photomask needs to be added. The alignment error accumulated in the process limits the accuracy of active channel size, thus it is not conducive to “miniaturization” of Thin Film Transistor devices.

Increasing pixel aperture ratio and decreasing the size of array substrate are conducive to miniaturization of array devices on the premise of preventing back channel etching damage.

### SUMMARY

The application provides an array substrate, a manufacturing method thereof and a display panel to increase pixel aperture ratio.

The application also discloses an array substrate. The array substrate includes: a Thin Film Transistor, including a substrate, Metal 1, an insulating layer, a semiconductor layer, a barrier layer, Metal 2, a first passivation layer, a pixel electrode, a first contact hole and a second contact hole, where the Metal 1 is disposed on the surface of the substrate; the insulating layer covers a surface of the Metal 1; the semiconductor layer covers a surface of the insulating layer; the barrier layer covers surfaces of the semiconductor layer and the insulating layer; the Metal 2 covers a surface of the barrier layer; the Metal 2 includes a source electrode and a drain electrode. The first passivation layer covers a surface of the Metal 2; the pixel electrode is disposed above the first passivation layer; the first contact hole connects the pixel electrode and the drain electrode; the second contact hole connects the drain electrode and the semiconductor layer; the first contact hole and the second contact hole overlap in a direction perpendicular to the array substrate.

Optionally, the first contact hole and the second contact hole partially overlap in a direction perpendicular to the array substrate.

Optionally, the first contact hole and the second contact hole completely overlap in a direction perpendicular to the array substrate.

Optionally, a side edge of the drain electrode exceeds a side edge of the Metal 1.

Optionally, the Thin Film Transistor further includes: a color photoresist layer covering a surface of the first passivation layer; a second passivation layer covering the a surface of the color photoresist layer; the pixel electrode covers the surface of the second passivation layer; the first contact hole penetrates through the first passivation layer, the color photoresist layer and the second passivation layer, and the pixel electrode is connected to the drain electrode through the first contact hole.

Optionally, the aperture of the first contact hole corresponding to the first passivation layer is smaller than the apertures of the first contact hole corresponding to the color photoresist layer and the second passivation layer.

Optionally, the pixel electrode directly covers the surface of the first passivation layer, and the first contact hole is connected to the drain electrode through the first passivation layer and the pixel electrode layer.

Optionally, the Thin Film Transistor further includes a third contact hole communicating with the source electrode and the semiconductor layer and connecting the drain electrode and the semiconductor with the second contact hole to form a via.

Optionally, the Metal 1 is a gate electrode.

Optionally, the aperture of the first contact hole is the same as that of the second contact hole.

Optionally, the first contact hole has an isosceles trapezoid shape.

The present application also discloses a manufacturing method of the array substrate, and the manufacturing method of the array substrate includes:

providing a Metal 1 and an insulating layer on the substrate;

providing a semiconductor layer and a barrier layer on the insulating layer, and a second contact hole and a third contact hole;

providing a Metal 2 on the barrier layer;

providing a first passivation layer on the second metal layer;

providing a color photoresist layer above the first passivation layer;

providing a second passivation layer on the color photoresist layer;

providing a pixel electrode on the second passivation layer; and

the first contact hole is disposed at a position on the first passivation layer, the color photoresist layer, and the second passivation layer overlapping the position of the second contact hole.

The present application also discloses a display panel, the display panel includes an array substrate, and the array substrate includes a Thin Film Transistor, and the Thin Film Transistor includes:

a substrate; a Metal 1 disposed on a surface of the substrate; an insulating layer covering a surface of the first metal layer; a semiconductor layer covering a surface of the insulating layer; a barrier layer covering surfaces of the semiconductor layer and the insulating layer a Metal 2 covering a surface of the barrier layer, the Metal 2 including a source electrode and a drain electrode; a first passivation layer covering a surface of the Metal 2; a pixel electrode disposed above the first passivation layer; a first contact hole connecting the pixel electrode and the drain electrode; and a second contact hole connecting the drain electrode and the semiconductor layer; where the first contact hole and the second contact hole overlap in a direction perpendicular to the array substrate.

Optionally, the first contact hole and the second contact hole partially overlap in a direction perpendicular to the array substrate.

Optionally, the first contact hole and the second contact hole completely overlap in a direction perpendicular to the array substrate.

Optionally, a side edge of the drain electrode exceeds a side edge of the Metal 1.

Optionally, the Thin Film Transistor includes:

a color photoresist layer covering a surface of the first passivation layer; a second passivation layer covering a surface of the color photoresist layer, the pixel electrode covers a surface of the second passivation layer; the first contact hole penetrates through the first passivation layer, the color photoresist layer and the second passivation layer, and the pixel electrode is connected to the drain electrode through the first contact hole.

Optionally, the insulating layer is a gate-oxide insulating layer.

Optionally, the Thin Film Transistor further includes a third contact hole communicating with the source and the semiconductor layer and connecting the drain and the semiconductor with the second contact hole to form a via.

Optionally, the first contact hole, the second contact hole and the third contact hole have the same shape.

Compared with an exemplary array substrate device, the accumulated alignment deviation of the process limits the accuracy of the active channel size and is not conducive to the “miniaturization” of the Thin Film Transistor device. In the present application, the first contact hole and the second contact hole overlap to reduce the area ratio of the contact hole, so that the Thin Film Transistor device can be placed horizontally; the array substrate and the via holes can be arranged on the same horizontal line, thereby increasing the aperture ratio and improving the penetration ratio of the panel.

### BRIEF DESCRIPTION OF DRAWINGS

The accompanying drawings, which are included to provide a further understanding of embodiments of the present application and constitute a part of the specification, illustrate embodiments of the application and, together with the text description, explain the principles of the application. Obviously, the drawings in the following description are merely some embodiments of the present application, and those skilled in the art can obtain other drawings according to the drawings without any inventive labor. In the drawings:

FIG. 1 is a top view of a Thin Film Transistor of one or more embodiments of the present application;

FIG. 2 is a cross-sectional view taken along line A-A′ of FIG. 1 of one or more embodiments of the present application;

FIG. 3 is a cross-sectional view taken along line A-A′ of FIG. 1 of one or more embodiments of the present application;

FIG. 4 is a cross-sectional view taken along line A-A′ of FIG. 1 of one or more embodiments of the present application;

FIG. 5 is a schematic diagram of a method of an array substrate of one or more embodiments of the present application.

### DETAILED DESCRIPTION OF EMBODIMENTS

It should be understood that the terminology, specific structural and functional details disclosed are merely exemplary for the purpose of describing specific embodiments. However, the present application may be embodied in many alternative forms and should not be construed as being limited to the embodiments set forth herein.

In the description of the present application, the terms “first” and “second” are only for the purpose of description and cannot be construed as indicating or implying relative importance or implicitly indicating the number of technical features indicated. Therefore, unless otherwise stated, a feature defined as “first,” and “second,” may explicitly or implicitly include one or more of the features; “multiple” means two or more. The term “include” and any variations thereof is intended to be inclusive, and may include or add one or more other features, integers, steps, operations, units, components and/or combinations thereof.

In addition, the terms “center”, “horizontally”, “up”, “down”, “left”, “right”, “vertical”, “horizontal”, “top”, “bottom”, “inner”, “outer” and the like for indicating an orientation or positional relationship are based on the description of the orientation or relative positional relationship shown in the accompanying drawings, and are only simplified description facilitating description of the application, and are not intended to indicate that the device or element referred to must have a particular orientation, be configured and operated in a particular orientation, and therefore cannot be construed as limiting the present application.

In addition, unless expressly specified and defined otherwise, the terms “mount”, “attach” and “connect” shall be used in a broad sense, and can be, for example, a fixed connection, a detachable connection, or an integral connection; it can be a mechanical connection or an electrical connection; it can be a direct connection or an indirect connection through an intermediate medium, and can be an internal connection between two elements. For those skilled in the art, the specific meaning of the above terms in this application can be understood according to the specific circumstances.

The present application will now be further described by reference to the accompanying drawings.

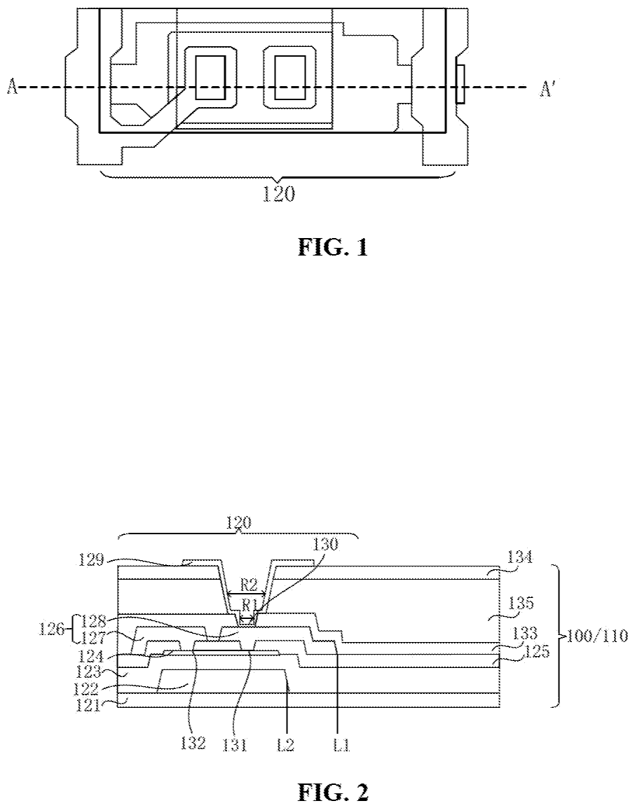

As shown in FIGS. 1 to 2, one or more embodiments of the application discloses an array substrate 110, including: a Thin Film Transistor 120, where the Thin Film Transistor 120 includes a substrate 121, a Metal 1 122, an insulating layer 123, a semiconductor 124, a barrier layer 125, a Metal 2 126, a first passivation layer 133, a pixel electrode 129, a first contact hole 130 and a second contact hole 131; the Metal 1 is disposed on the surface of the substrate 121; the insulating layer 123 covers the surface of the Metal 1 122; the semiconductor layer 124 covers the surface of the insulating layer 123; the barrier layer 125 covers the surfaces of the semiconductor layer 124 and the insulating layer 123; the Metal 2 126 covers the surface of the barrier layer 125; the Metal 2 126 includes a source electrode 127 and a drain electrode 128; the first passivation layer 133 covers the surface of the Metal 2 126; the pixel electrode 129 is disposed above the first passivation layer 133; the first contact hole 130 connects the pixel electrode 129 and the drain electrode 128; the second contact hole 131 connects the drain electrode 128 and the semiconductor layer 124; the first contact 130 and the second contact hole 131 overlap in a direction perpendicular to the array substrate 110.

In the solution, compared with an exemplary array substrate 110 device, the accumulated alignment deviation of the process limits the accuracy of the active channel size and is not conducive to the “miniaturization” of the TFT device. In the present application, the first contact hole 130 and the second contact hole 131 overlap to reduce the area ratio of the contact hole, so that the Thin Film Transistor device can be placed horizontally; the array substrate 110 and the via holes can be arranged on the same horizontal line, thereby increasing the aperture ratio and improving the penetration ratio of the panel.

Of course, the display panel 100 of the solution is applicable to the display that is adjacent to the pixel electrode 129 above the first passivation layer 133, and is also applicable to the display panel having other layers above the first passivation layer 133. The pixel electrode 129 is disposed above the first passivation layer 133, and the possibility of other layers above the first passivation layer 133 is not excluded. The Metal 1 122 is a gate electrode, and the Metal 2 126 includes a source electrode 127 and a drain electrode 128.

As shown in FIG. 2, in one or more embodiments, the first contact hole 130 and the second contact hole 131 completely overlap in a direction perpendicular to the array substrate 110. The first contact hole 130 and the second contact hole 131 completely overlap to maximize the lateral space of pixel, thereby placing the Thin Film Transistor 120 horizontally and reducing the longitudinal space proportion of pixel gate, thereby maximizing the opening area, aperture ratio and penetration ratio.

As shown in FIG. 2, in one or more embodiments, a side edge of the drain electrode 128 extends beyond a side edge of the Metal 1 122. In this solution, the side edge of the drain electrode 128 is L1 and the side edge of the Metal 1 122 is L2. The drain electrode 128 is shorter than the exemplary drain electrode 128 and saves cost. The side edge L1 of the drain electrode 128 extends beyond the side edge L2 of the Metal 1 122. Compared with the Metal 1 122, the horizontally extended drain electrode 128 reduces the capacitance of the source electrode 127 and the gate electrode. The signal transmission delay will be increased if the extended regions are removed.

As shown in FIG. 2, in one or more embodiments, the Thin Film Transistor 120 further includes: a color photoresist layer 135 covering a surface of the first passivation layer 133; a second passivation layer 134 covering a surface of the color photoresist layer 135; a pixel electrode 129 covering a surface of the second passivation layer 134; a first contact hole 130 penetrating through the first passivation layer 133, the color photoresist layer 135 and the second passivation layer 134, and the pixel electrode 129 connected to the drain electrode 128 through the first contact hole 130. In this solution, the color photoresist layer 135 is a red resist layer 135, and may also be a green resist layer 135 and a blue resist layer 135. The first contact hole 130 penetrates through the first passivation layer 133, the color photoresist layer 135 and the second passivation layer 134 to be connected to the drain electrode 128, and is directly connected to the drain electrode 128. On the premise of the color photoresist layer 135, the effect of overlapping the contact holes and increasing the pixel aperture ratio is more obvious.

As shown in FIG. 2, in one or more embodiments, the aperture of the first contact hole 130 corresponding to the first passivation layer 133 is smaller than the apertures of the first contact hole corresponding to the color photoresist layer 135 and the second passivation layer 134. The aperture penetrating through the first passivation layer 133 is R1, the aperture penetrating through the color photoresist layer 135 is R2, and the two apertures are different. In order to prevent the pixel electrode 129 from being disconnected when the via is too deep, thereby causing the signal transmission path failure, one aperture is large and the other is small. Therefore, when the pixel electrode 129 is coated in this manner, a buffer is provided to make the transmission path smoother.

As shown in FIG. 2, in one or more embodiments, the Thin Film Transistor 120 further includes a third contact hole 132 connecting the source electrode 127 with the semiconductor layer 124. The third contact hole 132 connects the source electrode 127 with the semiconductor layer 124, and forms a via with the drain electrode 128 and the semiconductor connected by the second contact hole 131.

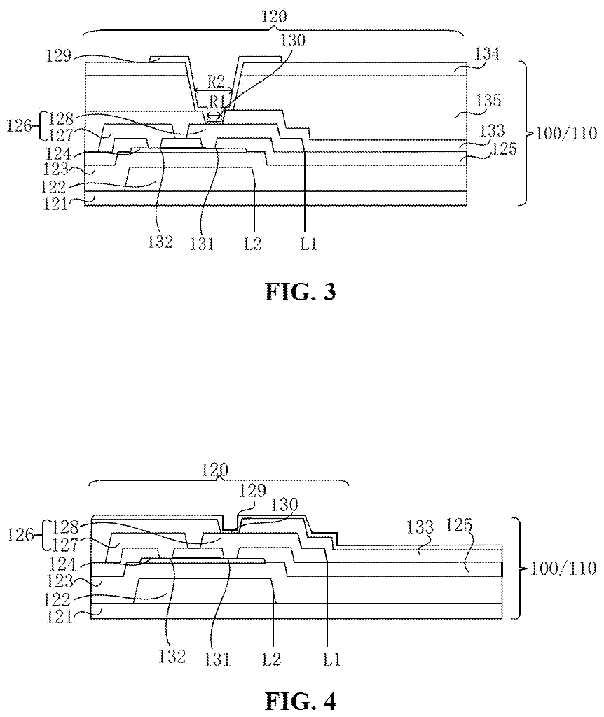

As shown in FIG. 3, in one or more embodiments, the first contact hole 130 and the second contact hole 131 partially overlap in a direction perpendicular to the array substrate 110. In this solution, the first contact hole 130 partially overlaps with the second contact hole 131, which makes it easier to reduce the structure of the device than in the exemplary embodiment. The overlap of the contact holes directly reduces the area ratio in the lateral space and reduces the size of the device.

As shown in FIG. 4, in one or more embodiments, the pixel electrode 129 directly covers the surface of the first passivation layer 133, and the first contact hole 130 is connected to the drain electrode 128 through the first passivation layer 133 and the pixel electrode 129 layer. In this solution, the plurality of contact holes of the structural Thin Film Transistor 120 can also reduce the size of the device after being overlapped. Without the color photoresist layer 135, the first contact hole 130 is connected to the drain electrode 128 through the first passivation layer 133 and the pixel electrode 129 layer, the signal transmission path is shorten, and the area ratio in the lateral space can be directly reduced after the contact holes overlap, thereby reducing the size of the device.

In one or more embodiments, the first contact hole 130 has the same aperture as the second contact hole 131. With the same aperture, the first contact hole 130 and the second contact hole 131 can maintain the same transmission signal rate without increasing the resistance and affecting the transmission rate because of a certain small aperture.

In one or more embodiments, the first contact hole 130 has an isosceles trapezoid shape. The first contact hole has an isosceles trapezoid shape, which facilitates the manufacture procedure.

As shown in FIGS. 1 to 4, as another embodiment of the present application, it discloses an array substrate 110. The array substrate 110 includes: a Thin Film Transistor 120, where the Thin Film Transistor 120 includes a substrate 121, a Metal 1 122, an insulating layer 123, a semiconductor 124, a barrier layer 125, a Metal 2 126, a first passivation layer 133, a color photoresist layer 123, a second passivation layer 134, a pixel electrode 129, a first contact hole 130 and a second contact hole 131; the Metal 1 is disposed on the surface of the substrate 121; the insulating layer 123 covers the surface of the Metal 1 122; the semiconductor layer 124 covers the surface of the insulating layer 123; the barrier layer 125 covers the surfaces of the semiconductor layer 124 and the insulating layer 123; the Metal 2 126 covers the surface of the barrier layer 125; the Metal 2 126 includes a source electrode 127 and a drain electrode 128; the first passivation layer 133 covers the surface of the Metal 2 126; the color photoresist layer 135 covers the surface of the first passivation layer 133, the second passivation layer 134 covers the surface of the color photoresist layer 135, and the pixel electrode 129 covers the surface of the second passivation layer 134; the first contact hole 130 penetrates through the first passivation layer 133, the color photoresist layer 135 and the second passivation layer 134, the pixel electrode 129 is connected to the drain electrode 128 through the first contact hole 130, and the second contact hole 131 connects the drain electrode 128 and the semiconductor layer 124; the first contact hole 130 and the second contact hole 131 overlap in a direction perpendicular to the array substrate 110.

In this solution, compared with an exemplary array substrate 110 device, the accumulated alignment deviation of the process limits the accuracy of the active channel size and is not conducive to the “miniaturization” of the TFT device. The first contact hole 130 of the present application penetrates through the first passivation layer 133, the color photoresist layer 135 and the second passivation layer 134, and is directly connected to the drain electrode 128. On the premise of the color photoresist layer 135, the effect of overlapping the contact holes and increasing the pixel aperture ratio is more obvious. In this application, the first contact hole 130 and the second contact hole 131 overlap to reduce the area ratio of the contact hole, so that the Thin Film Transistor device can be placed horizontally; the array substrate 110 and the via holes can be arranged on the same horizontal line, thereby increasing the aperture ratio and improving the penetration ratio of the panel.

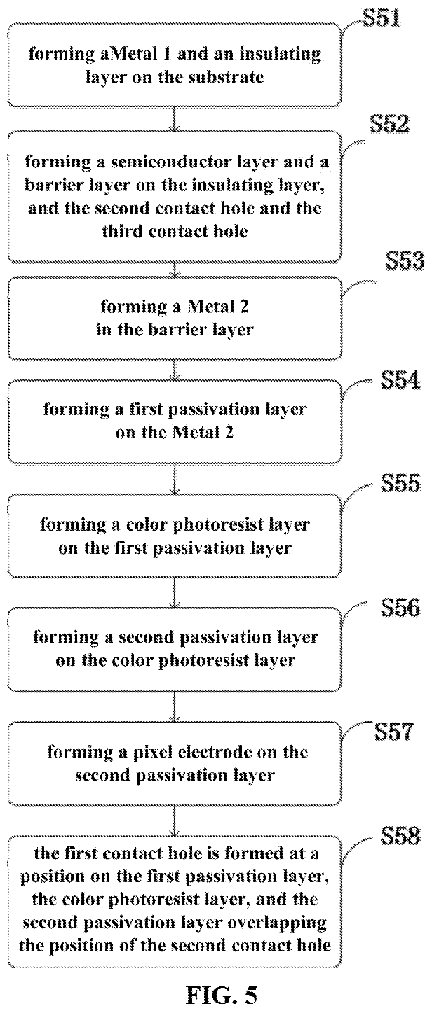

As shown in FIG. 5, as another embodiment of the present application, it discloses a manufacturing method of an array substrate 110. The manufacturing method of the array substrate 110 includes:

S51: providing a Metal 1 and an insulating layer on the substrate;

S52: providing a semiconductor layer and a barrier layer on the insulating layer, and a second contact hole and a third contact hole;

S53: providing a Metal 2 on the barrier layer;

S55: providing a first passivation layer on the second metal layer;

S52: providing a color photoresist layer above the first passivation layer;

S56: providing a second passivation layer on the color photoresist layer;

S57: providing a pixel electrode on the second passivation layer; and

S58: the first contact hole is disposed at a position on the first passivation layer, the color photoresist layer, and the second passivation layer overlapping the position of the second contact hole.

As shown in FIGS. 1 to 5, as another embodiment of the present application, it discloses a display panel 100. The display panel 100 includes an array substrate 110, the array substrate 110 includes a Thin Film Transistor 120, and the Thin Film Transistor 120 includes:

a substrate 121; a Metal 1 122 disposed on the surface of the substrate 121; an insulating layer 123 covering the surface of the Metal 1 122; a semiconductor layer 124 covering the surface of the insulating layer 123; a barrier layer 125 covering surfaces of the semiconductor layer 124 and the insulating layer 123; a Metal 2 126 covering the surface of the barrier layer 125,

and the Metal 2 126 including a source electrode 127 and a drain electrode 128; a first passivation layer 133 covering the surface of the Metal 2 126; a pixel electrode 129 disposed above the first passivation layer 133; a first contact hole 130 connecting the pixel electrode 129 and the drain electrode 128; a second contact hole 131 connecting the drain electrode 128 and the semiconductor layer 124; and the first contact hole 130 and the second contact 131 hole overlap in a direction perpendicular to the array substrate 110.

In this solution, the display panel 100 of the solution is applicable to the display which is adjacent to the pixel electrode 129 above the first passivation layer 133, and is also applicable to the panel having other layers above the first passivation layer 133, with all layers clinging to the surface. The pixel electrode 129 is disposed above the first passivation layer 133, and the possibility of other layers above the first passivation layer 133 is not excluded. The Metal 1 122 is a gate electrode, and the Metal 2 126 includes a source electrode 127 and a drain electrode 128. Compared with an exemplary array substrate 110 device, the accumulated alignment deviation of the process limits the accuracy of the active channel size and is not conducive to the “miniaturization” of the TFT device. In the present application, the first contact hole 130 and the second contact hole 131 overlap to reduce the area ratio of the contact hole, so that the Thin Film Transistor device can be placed horizontally; the array substrate 110 and the via holes can be arranged on the same horizontal line, thereby increasing the aperture ratio and improving the penetration ratio of the panel.

In one or more embodiments, the first contact hole 130 and the second contact hole 131 partially overlap in a direction perpendicular to the array substrate 110. The first contact hole 130 partially overlaps with the second contact hole 131, which makes it easier to reduce the structure of the device than in the exemplary embodiment. The overlap of the contact holes directly reduces the area ratio in the lateral space and reduces the size of the device.

In one or more embodiments, the first contact hole 130 and the second contact hole 131 completely overlap in a direction perpendicular to the array substrate 110. The first contact hole 130 and the second contact hole 131 completely overlap to maximize the lateral space of pixel, thereby placing the Thin Film Transistor 120 horizontally and reducing the longitudinal space proportion of pixel gate, thereby maximizing the opening area, aperture ratio and penetration ratio.

In one or more embodiments, a side edge of the drain electrode 128 extends beyond a side edge of the Metal 1 122. The side edge of the drain electrode 128 is L1 and the side edge of the Metal 1 122 is L2. The drain electrode 128 is shorter than the exemplary drain electrode 128 and saves cost. The side edge L1 of the drain electrode 128 extends beyond the side edge L2 of the Metal 1 122. Compared with the Metal 1 122, the horizontally extended drain electrode 128 reduces the capacitance of the source electrode 127 and the gate electrode. The signal transmission delay will be increased if the extended regions are removed.

In one or more embodiments, the Thin Film Transistor 120 further includes:

a color photoresist layer 135 covering the surface of the first passivation layer 133; a second passivation layer 134 covering the surface of the color photoresist layer 135; a pixel electrode 129 covering the surface of the second passivation layer 134; and

the first contact hole 131 penetrates through the first passivation layer 133, the color photoresist layer 135 and the second passivation layer 134, and the pixel electrode 1219 is connected to the drain electrode 128 through the first contact hole 130.

In this solution, the color photoresist layer 135 is a red resist layer 135, and may also be a green resist layer 135 and a blue resist layer 135. The first contact hole 130 penetrates through the first passivation layer 133, the color photoresist layer 135 and the second passivation layer 134, and is directly connected to the drain electrode 128. On the premise of the color photoresist layer 135, the effect of overlapping the contact holes and increasing the pixel aperture ratio is more obvious.

In one or more embodiments, the insulating layer is a gate-oxide insulating layer, which is easy to block the mobility of electrons and has a good insulating effect.

In one or more embodiments, the Thin Film Transistor further includes a third contact hole communicating with the source electrode and the semiconductor layer and connecting the drain electrode and the semiconductor with the second contact hole to form a via.

In one or more embodiments, the first contact hole, the second contact hole and the third contact hole have the same shape. The range of electron migration is the same, thus the components will not be damaged due to unbalanced electron transport caused by too big contact holes.

It should be noted: for limits to the steps involved in this solution, without influence the implementation of the specific solution, it is not recognized as limiting the sequence of steps, and the previous steps may be executed first, later, or even simultaneously, and shall be deemed to fall within the scope of the present application as long as the solution can be implemented.

The technical solution of the present application can be applied to a wide variety of display panels, such as TN type display panels (referred to as twisted nematic panels), IPS type display panels (In-Plane Switching), VA type display panels (Multi-domain Vertical Alignment), and, of course, other types of display panels, such as organic light emitting diode (OLED).

The above content is a detailed description of the present application in conjunction with specific embodiments, and it is not to be construed that specific embodiments of the present application are limited to these descriptions. For those of ordinary skill in the art to which this application belongs, a number of simple derivations or substitutions may be made without departing from the spirit of this application, all of which shall be deemed to fall within the scope of this application.

What is claimed is:

1. An array substrate, comprising a Thin Film Transistor (TFT),
wherein the Thin Film Transistor comprising:
a substrate;
a Metal 1 disposed on a surface of the substrate;
an insulating layer covering a surface of the first metal layer;
a semiconductor layer covering a surface of the insulating layer;
a barrier layer covering surfaces of the semiconductor layer and the insulating layer;
a Metal 2 covering a surface of the barrier layer, the Metal 2 comprising a source electrode and a drain electrode;
a first passivation layer covering a surface of the Metal 2;
a pixel electrode disposed above the first passivation layer;
a first contact hole connecting the pixel electrode and the drain electrode; and
a second contact hole connecting the drain electrode and the semiconductor layer;
wherein the first contact hole and the second contact hole overlap in a direction perpendicular to the array substrate.

2. The array substrate according to claim 1, wherein the first contact hole and the second contact hole partially overlap in a direction perpendicular to the array substrate.

3. The array substrate according to claim 1, wherein the first contact hole and the second contact hole completely overlap in a direction perpendicular to the array substrate.

4. The array substrate according to claim 1, wherein a side edge of the drain electrode exceeds a side edge of the first metal layer.

5. The array substrate according to claim 1, wherein the Thin Film Transistor further comprising:
a color photoresist layer covering a surface of the first passivation layer;
a second passivation layer covering a surface of the color photoresist layer;
the pixel electrode covers a surface of the second passivation layer;
the first contact hole penetrates through the first passivation layer, the color photoresist layer and the second passivation layer, and the pixel electrode is connected to the drain electrode through the first contact hole.

6. The array substrate according to claim 5, wherein the aperture of the first contact hole corresponding to the first passivation layer is smaller than the apertures of the first contact hole corresponding to the color photoresist layer and the second passivation layer.

7. The array substrate according to claim 1, wherein the pixel electrode directly covers the surface of the first passivation layer, and the first contact hole is connected to the drain electrode through the first passivation layer and the pixel electrode layer.

8. The array substrate according to claim 1, wherein the Thin Film Transistor further comprising a third contact hole communicating with the source electrode and the semiconductor layer and connecting the drain electrode and the semiconductor with the second contact hole to form a via.

9. The array substrate according to claim 1, wherein the Metal 1 is a gate electrode.

10. The array substrate according to claim 1, wherein the aperture of the first contact hole is the same as that of the second contact hole.

11. The array substrate according to claim 1, wherein the first contact hole has an isosceles trapezoid shape.

12. A manufacturing method of an array substrate, wherein the manufacturing method of the array substrate comprising:
providing a Metal 1 and an insulating layer on the substrate;
providing a semiconductor layer and a barrier layer on the insulating layer, and a second contact hole and a third contact hole;
providing a Metal 2 on the barrier layer;
providing a first passivation layer on the second metal layer;
providing a color photoresist layer above the first passivation layer;
providing a second passivation layer on the color photoresist layer;
providing a pixel electrode on the second passivation layer; and
the first contact hole is disposed on the first passivation layer, the color resist layer, and the second passivation layer corresponding to the position of the second contact hole.

13. A display panel comprising an array substrate, the array substrate comprising a Thin Film Transistor,
wherein the Thin Film Transistor comprising:
a substrate;
a Metal 1 disposed on a surface of the substrate;
an insulating layer covering a surface of the first metal layer;
a semiconductor layer covering a surface of the insulating layer;
a barrier layer covering surfaces of the semiconductor layer and the insulating layer;
a Metal 2 covering a surface of the barrier layer, the Metal 2 comprising a source electrode and a drain electrode;
a first passivation layer covering a surface of the Metal 2;
a pixel electrode disposed above the first passivation layer;
a first contact hole connecting the pixel electrode and the drain electrode; and
a second contact hole connecting the drain electrode and the semiconductor layer;
wherein the first contact hole and the second contact hole overlap in a direction perpendicular to the array substrate.

14. The display panel according to claim 13, wherein the first contact hole and the second contact hole partially overlap in a direction perpendicular to the array substrate.

15. The display panel according to claim 13, wherein the first contact hole and the second contact hole completely overlap in a direction perpendicular to the array substrate.

16. The display panel according to claim 13, wherein a side edge of the drain electrode exceeds a side edge of the Metal 1.

17. The display panel according to claim 13, wherein the Thin Film Transistor further comprising:
a color photoresist layer covering a surface of the first passivation layer;
a second passivation layer covering a surface of the color photoresist layer;
the pixel electrode covers a surface of the second passivation layer;
the first contact hole penetrates through the first passivation layer, the color photoresist layer and the second passivation layer, and the pixel electrode is connected to the drain electrode through the first contact hole.

18. The display panel according to claim 13, wherein the insulating layer is a gate-oxide insulating layer.

19. The display panel according to claim 13, wherein the Thin Film Transistor further comprising a third contact hole communicating with the source electrode and the semiconductor layer and connecting the drain electrode and the semiconductor with the second contact hole to form a via.

20. The display panel according to claim 18, wherein the first contact hole, the second contact hole and the third contact hole have the same shape.
